(19) United States
(12) Patent Application Publication
(10) Pub. No.: US 2026/0082620 A1
(43) Pub. Date: Mar. 19, 2026

(54) TRANSISTOR STRUCTURE AND MANUFACTURING METHOD THEREOF

(71) Applicant: Silergy Semiconductor Technology (Hangzhou) LTD, Hangzhou (CN)

(72) Inventors: Hui Yu, Hangzhou (CN); Song Pu, Hangzhou (CN); Zhaofeng Sun, Hangzhou (CN); Jun Cai, Hangzhou (CN)

(21) Appl. No.: 19/320,056

(22) Filed: Sep. 5, 2025

(30) Foreign Application Priority Data
Sep. 14, 2024 (CN) 202411296000.0

(51) Int. Cl. H10D 30/65; H01L 23/522; H10D 30/01; H10D 62/10; H10D 64/27

(52) U.S. Cl. CPC H10D 30/65; H10D 30/0281; H10D 62/102; H10D 62/111; H10D 62/115; H10D 64/518; H10W 20/42

(57) ABSTRACT

A transistor structure can include: a source region and a drain region located in a semiconductor region; a gate dielectric layer located on the upper surface of the semiconductor region; a field isolation barrier layer located on the semiconductor region, and extending laterally from the gate dielectric layer at least above the drain region and covering the upper surface of the drain region, where the field isolation barrier layer includes at least one drain via on the upper surface of the drain region; and a drain electrode filling the drain via to be in contact with the drain region.

### RELATED APPLICATIONS

This application claims the benefit of Chinese Patent Application No. 202411296000.0, filed on Sep. 14, 2024, which is incorporated herein by reference in its entirety.

### FIELD OF THE INVENTION

The present invention generally relates to the field of semiconductor technology, and more particularly to semiconductor devices including transistor structures and methods of mailing transistor structures.

### BACKGROUND

A switched-mode power supply (SMPS), or a “switching” power supply, can include a power stage circuit and a control circuit. When there is an input voltage, the control circuit can consider internal parameters and external load changes, and may regulate the on/off times of the switch system in the power stage circuit. Switching power supplies have a wide variety of applications in modern electronics. For example, switching power supplies can be used to drive light-emitting diode (LED) loads. Power switches can be semiconducting devices, including metal-oxide-semiconductor field-effect transistors (MOSFETs) and insulated gate bipolar transistors (IGBTs), among others. For example, laterally-diffused metal-oxide-semiconductor (LDMOS) devices are widely used in such on-off type regulators.

### BRIEF DESCRIPTION OF THE DRAWINGS

FIG. 1 is a cross-sectional view of a first example transistor structure, in accordance with embodiments of the present invention.

FIG. 2 is a cross-sectional view of a second example transistor structure, in accordance with embodiments of the present invention.

FIG. 3 is a cross-sectional view of a third example transistor structure, in accordance with embodiments of the present invention.

FIG. 4 is a cross-sectional view of a fourth example transistor structure, in accordance with embodiments of the present invention.

FIG. 5 shows a cross-sectional view of a fifth example transistor structure, in accordance with embodiments of the present invention.

FIGS. 6 and 7 are top views of two example types of drain vias in the transistor structure, in accordance with embodiments of the present invention.

FIG. 8 is a cross-sectional view of an example of forming an interlayer dielectric layer in the transistor structure, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Further, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

Semiconductor devices are generally manufactured using two complex manufacturing processes: front-end manufacturing and back-end manufacturing. Front-end manufacturing may involve the formation of a plurality of die on the surface of a semiconductor wafer. Each die on the wafer may contain active and passive electrical components, which are electrically connected to form functional electrical circuits. Active electrical components, such as transistors and diodes, have the ability to control the flow of electrical current. Passive electrical components, such as capacitors, inductors, resistors, and transformers, create a relationship between voltage and current necessary to perform electrical circuit functions.

Passive and active components can be formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition may involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. The portion of the photoresist pattern subjected to light is removed using a solvent, exposing portions of the underlying layer to be patterned. The remainder of the photoresist may be removed, leaving behind a patterned layer. Alternatively, some types of materials can be patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface may be used to produce smaller and more densely packed active and passive components. Planarization can be used to remove material from the surface of the wafer and produce a uniformly flat surface. Planarization can involve polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

Back-end manufacturing refers to cutting or singulating the finished wafer into the individual die and then packaging the die for structural support and environmental isolation. To singulate the die, the wafer is scored and broken along non-functional regions of the wafer called saw streets or scribes. The wafer may be singulated using a laser cutting tool or saw blade. After singulation, the individual die can be mounted to a package substrate that can include pins or contact pads for interconnection with other system components. Contact pads formed over the semiconductor die can then be connected to contact pads within the package. The electrical connections can be made with solder bumps, stud bumps, conductive paste, or wire bonds, as a few examples. An encapsulant or other molding material may be deposited over the package to provide physical support and electrical isolation. The finished package can then be inserted into an electrical system and the functionality of the semiconductor device is made available to the other system components.

High voltage and high current impose increasingly higher requirements on laterally-diffused metal-oxide-semiconductor (LDMOS) devices. On one hand, the chip area of high-current application products depends on the generation-by-generation reduction of specific on-resistance Rsp, placing high demands on the extreme optimization of the trade-off between breakdown voltage and specific on-resistance. On the other hand, under high current applications, higher requirements are placed on the reliability of the device's high current short-circuit capability.

For LDMOS devices, both the contact between the source electrode and the source region, and the contact between the drain electrode and the drain region, are typically metal silicide contacts. The width of the metal silicide blocking layer (e.g., salicide block [SAB]) and the spacing between the drain electrode and the SAB follow the design rules of the SAB, which can increase the device size and thus increase the specific on-resistance of the device.

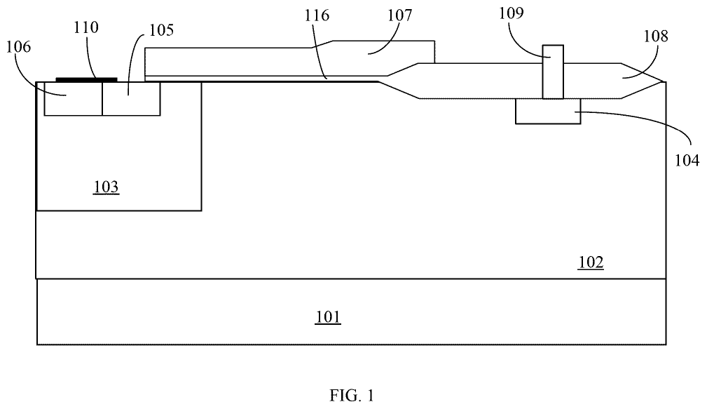

Referring now to FIG. 1, shown is a cross-sectional view of a first example transistor structure, in accordance with embodiments of the present invention. In this particular example, the transistor structure can include semiconductor region 102, source region 105, and drain region 104 located in semiconductor region 102, gate dielectric layer 116 located on the upper surface of the semiconductor region, and field isolation barrier layer 108 located on the semiconductor region and extending from gate dielectric layer 116 at least to drain region 104 and covering the upper surface of drain region 104. Field isolation barrier layer 108 can also include at least one drain via therein to expose the upper surface of drain region 104. The transistor structure can also include drain electrode 109 filling the drain via to be in contact with drain region 104. Field isolation barrier layer 108 can be in contact with semiconductor region 102. For example, the entire lower surface of field isolation barrier layer 108 may be in contact with semiconductor region 102.

The transistor structure can also include a gate structure, which can include gate dielectric layer 116 and gate conductor 107 located at least on gate dielectric layer 116. In this example, the thickness of field isolation barrier layer 108 may be greater than the thickness of gate dielectric layer 116. Field isolation barrier layer 108 can cover the upper surface of drain region 104, and the drain via may penetrate field isolation barrier layer 108. Field isolation barrier layer 108 can be a local oxidation of silicon (LOCOS) structure, or a thick dielectric layer formed on the upper surface of the semiconductor region (e.g., by deposition).

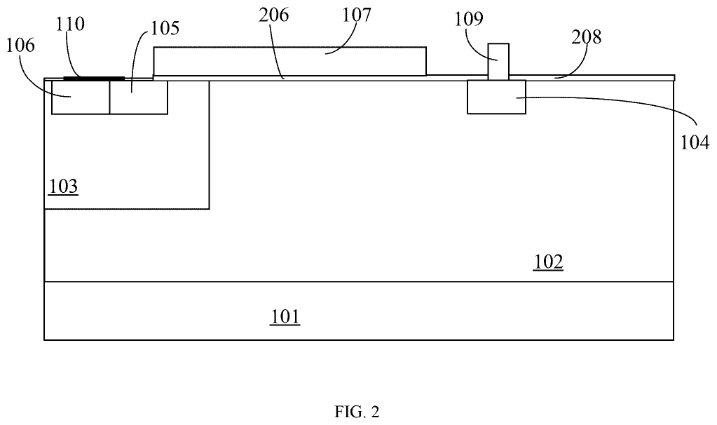

Referring now to FIG. 2, shown is a cross-sectional view of a second example transistor structure, in accordance with embodiments of the present invention. In this particular example, field isolation barrier layer 208 may have a uniform thickness that is close to the thickness of gate dielectric layer 206. In particular, field isolation barrier layer 208 may have the same thickness as gate dielectric layer 206. For example, field isolation barrier layer 208 and gate dielectric layer 206 can be formed simultaneously, in order to simplify the process. In one example, field isolation barrier layer 208 may be thicker than gate dielectric layer 206. In some cases, field isolation barrier layer 208 can be formed by using the same method for forming the gate dielectric layer.

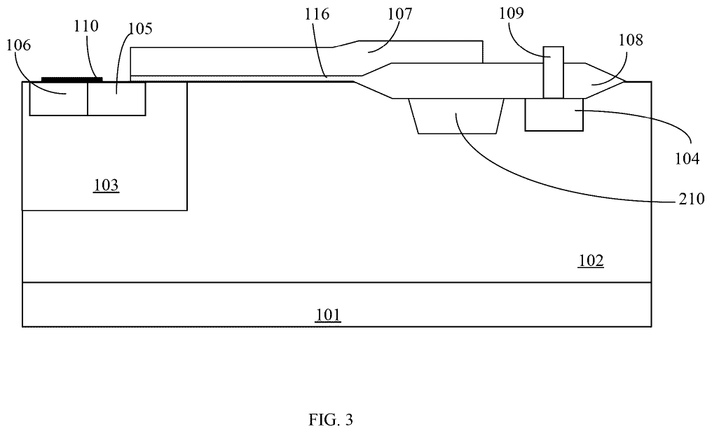

Referring now to FIG. 3, shown is a cross-sectional view of a third example transistor structure, in accordance with embodiments of the present invention. In this particular example, the transistor may also include shallow trench isolation (STI) 210 located below field isolation barrier layer 108, where shallow trench isolation 210 is located between source region 105 and drain region 104. Shallow trench isolation 210 and field isolation barrier layer 108 may combine to better optimize the electric field on the transistor surface and to improve the breakdown voltage of the transistor.

The drain via and gate conductor 107 can be spaced apart. The spacing between the drain via and gate conductor 107 may comply with the design rules of the device, such as be greater than or equal to the minimum design rule of the device or process technology. Under the device design rules, the spacing between the drain via and gate conductor 107 can increase as the device withstand voltage increases. The design rules of the device are related to the standard CMOS process. For example, the minimum design rule for the spacing between the drain via and gate conductor 107 in a 90 nm process can be set as 0.13 μm. In order to optimize the trade-off between the breakdown voltage and the on-resistance of the transistor without wasting the size of the transistor, the drain region can be located at an edge region of a second side opposite to a first side of the field isolation barrier layer, where the first side of the field isolation barrier layer is the side adjacent to the gate dielectric layer.

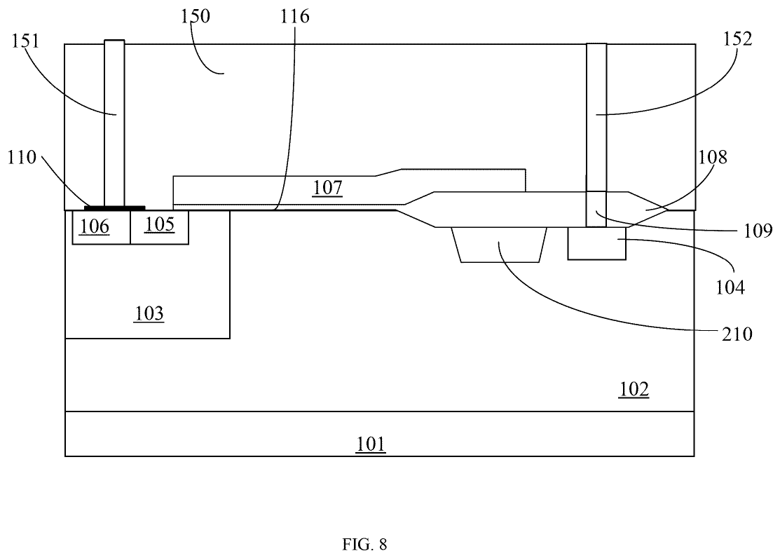

The example transistor structure can also include body region 103 of a first doped type located in the semiconductor region, and body contact region 106 of the first doped type located in body region 103 and adjacent to source region 105. The transistor structure (see, e.g., FIG. 8) can also include metal silicide layer 110 located on the upper surface of source region 105, interlayer dielectric layer 150 covering the upper surface of the above transistor structure, source via 151 that can penetrate through the interlayer dielectric layer and extend to metal silicide layer 110 to be in contact with metal silicide layer 110, and via 152 that can penetrate through the interlayer dielectric layer to match and effectively extend the drain via. In particular embodiments, the LDMOS transistor can also include substrate 101. The substrate can be of a second doped type, and the semiconductor region of a first doped type. Additionally, an epitaxial layer or a buried layer may be included between the substrate and the semiconductor region.

In particular embodiments, the drain region can be below the field isolation barrier layer, and a drain via may be formed through the field isolation barrier layer and extending to the drain region, thereby eliminating a step of forming metal silicide on the drain region. Consequently, there is no need to set the width of the metal silicide blocking layer (SAB) and the spacing between the drain electrode and the SAB according to the SAB design rules. In this way, the device size can be reduced, along with the specific on-resistance of the device.

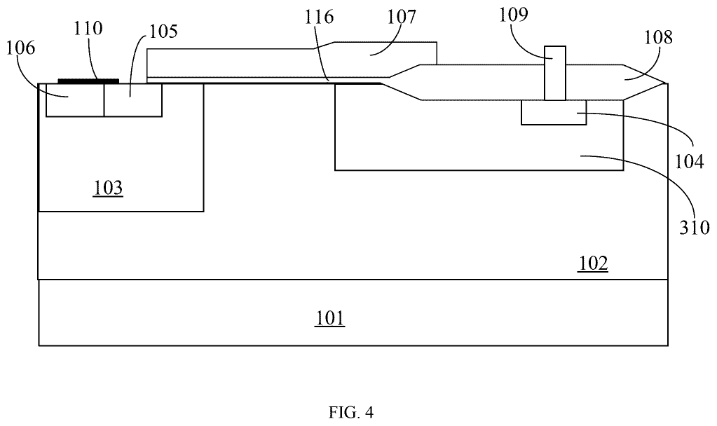

Referring now to FIG. 4, shown is a cross-sectional view of a fourth example transistor structure, in accordance with embodiments of the present invention. In this particular example, drift region 310 can be located in semiconductor region 102 and extending from the upper surface of semiconductor region 102 into its interior. Drift region 310 can be located at least below field isolation barrier layer 108. Drift region 310 may be of a second doped type, where, e.g., the first doped type is one of P-type or N-type, and the second doped type is the other of P-type or N-type. Drain region 104 can be located in drift region 310. In one alternate example, the drain region may not be located in drift region 310, but may instead be adjacent to the drift region. The drift region in this particular example can increase the concentration near the surface of the semiconductor region, in order to reduce the specific on-resistance of the transistor. Further, the combination of the drift region and the field isolation barrier layer can reduce the surface electric field of the transistor.

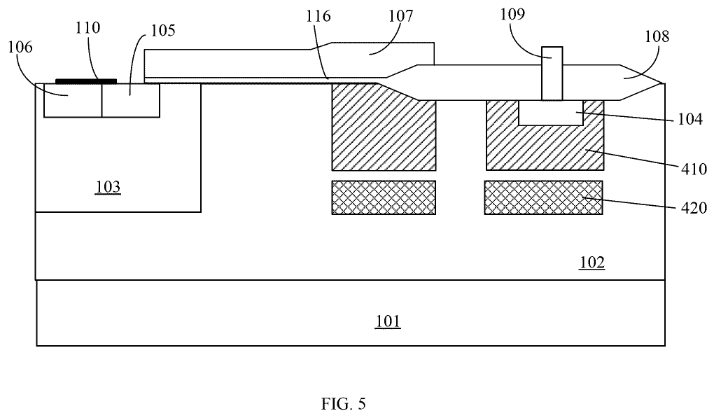

Referring now to FIG. 5, shown shows a cross-sectional view of a fifth example transistor structure, in accordance with embodiments of the present invention. In this particular example, the transistor structure can include a reduced surface field (RESURF) region of the first doped type, and a different structure of the drift region. In particular embodiments, RESURF region 420 can be disposed below drift region 410, in order to mutually deplete with the drift region, thereby reducing the surface electric field between the gate and drain of the transistor and improving the breakdown voltage of the transistor. RESURF region 420 can be in contact with body region 103, or may be separated from body region 103. The spacing between drift region 410 and RESURF region 420 can be greater than or equal to 0. In one example, drift region 410 and RESURF region 420 can be arranged laterally. In another example, RESURF region 420 can surround drift region 410. Particular embodiments may support any suitable positional relationship between drift region 410 and RESURF region 420.

In this particular example, in the lateral direction, drift region 410 can include a plurality of separated first doped regions, and RESURF region 420 can include a plurality of separated second doped regions. In other embodiments, drift region 410 can be a continuous doped region, and RESURF region 420 can be a continuous doped region. In this particular example, in the vertical direction, the number of layers for both drift region 410 and RESURF region 420 is one. In other examples, the number of layers for drift region 410 and RESURF region 420 can be multiple.

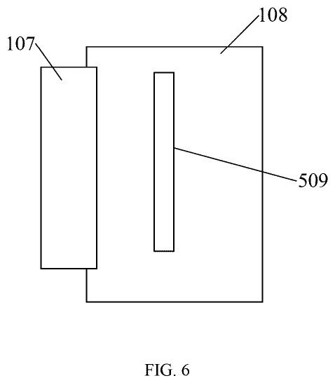

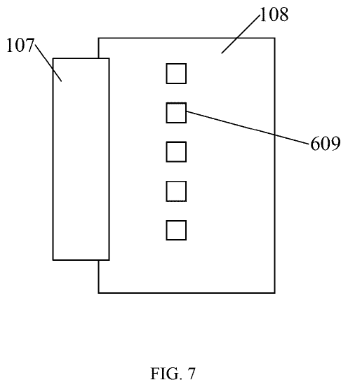

Referring now to FIGS. 6 and 7, shown are top views of two example types of drain vias in the transistor structure, in accordance with embodiments of the present invention. As shown in the example of FIG. 6, the drain via can be arranged as one continuous elongated hole 509 distributed along a length direction, where the width direction of the drain via is the direction from the source region to the drain region. As shown in the example of FIG. 7, the drain region via can be arranged as a plurality of sub-holes 609 distributed at intervals along a length direction, where the width direction of the drain via is the direction from the source region to the drain region. The length direction and the width direction are perpendicular, and any suitable number(s) and shape(s) of the drain via can be supported in certain embodiments.

Particular embodiments also provide a method of making a transistor structure. The method can be used to form the example transistors shown in FIGS. 1-5 but is not limited thereto. As follows, the formation of the transistor structure shown in FIG. 1 is used as an example for description. The example method can include forming source region 105 and drain region 104 in semiconductor region 102, forming gate dielectric layer 116 on the upper surface of semiconductor region 102, and forming field isolation barrier layer 108 on semiconductor region 102. Field isolation barrier layer 108 may extend from gate dielectric layer 116 at least above drain region 104, and can cover the upper surface of drain region 104. The method can also include forming a drain via penetrating through field isolation barrier layer 108, and filling the drain via to form a drain electrode 109, where the drain electrode is contact with the drain region.

For example, before forming source region 105 and drain region 104, the method can also include forming body region 103 in the semiconductor region. Before forming the body region, the method can also include forming gate conductor 107 on gate dielectric layer 116. Before forming the drain via, the method can also include forming metal silicide layer 110 on the surface of the source region. For example, the forming the metal silicide can include layer can include forming a metal silicide blocking layer to cover the upper surface of the semiconductor region and the field isolation barrier layer, the metal silicide blocking layer exposing the surface of the source region, and forming a metal silicide layer on the exposed surface of the source region.

Referring now to FIG. 8, shown is a cross-sectional view of an example of forming an interlayer dielectric layer in the transistor structure, in accordance with embodiments of the present invention. In this particular example, the transistor structure can also include forming interlayer dielectric layer 150 that covers above semiconductor region 102. Also, via 152 penetrating through the interlayer dielectric layer, and source via 151 penetrating through the interlayer dielectric layer to extend to metal silicide layer 110, can be formed.

For example, drain via 109 can merge with and effectively extend via 152 that is formed in the field isolation barrier layer by over-etching the field isolation barrier layer. Accordingly, the drain via may be formed in the field isolation barrier layer by over-etching, allowing the drain via and the source via to be completed synchronously. This can make the process of particular embodiments compatible with other processes without adding process steps, and thus achieving miniaturization of the transistor.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A transistor structure, comprising:
a) a source region and a drain region located in a semiconductor region;
b) a gate dielectric layer located on the upper surface of the semiconductor region;
c) a field isolation barrier layer located on the semiconductor region, and extending laterally from the gate dielectric layer at least above the drain region and covering the upper surface of the drain region, wherein the field isolation barrier layer comprises at least one drain via on the upper surface of the drain region; and
d) a drain electrode filling the drain via to be in contact with the drain region.

2. The transistor structure of claim 1, wherein the drain region is located at an edge of a second side opposite to a first side of the field isolation barrier layer, wherein the first side of the field isolation barrier layer is a side adjacent to the gate dielectric layer.

3. The transistor structure of claim 1, wherein the field isolation barrier layer is in contact with the semiconductor region.

4. The transistor structure of claim 1, wherein the field isolation barrier layer has a same thickness as the gate dielectric layer.

5. The transistor structure of claim 1, wherein the field isolation barrier layer has a uniform thickness.

6. The transistor structure of claim 1, wherein a thickness of the field isolation barrier layer is greater than a thickness of the gate dielectric layer.

7. The transistor structure of claim 1, further comprising a shallow trench isolation located below the field isolation barrier layer, wherein the shallow trench isolation is located between the source region and the drain region.

8. The transistor structure of claim 1, further comprising a metal silicide layer located on the upper surface of the source region.

9. The transistor structure of claim 1, further comprising:
a) a body region of a first doped type located in the semiconductor region;
b) a body contact region of the first doped type located in the body region and adjacent to the source region; and
c) a gate conductor located on the gate dielectric layer.

10. The transistor structure of claim 1, further comprising a drift region of a second doped type located in the semiconductor region, the drift region being located at least below the field isolation barrier layer.

11. The transistor structure of claim 10, further comprising a reduced surface field region of the first doped type located in the semiconductor region, wherein the reduced surface field region and the drift region mutually deplete each other.

12. The transistor structure of claim 1, wherein the drain via comprises one continuous elongated hole distributed along a length direction, wherein a width direction of the drain via is a direction from the source region to the drain region, and the length direction is perpendicular to the width direction.

13. The transistor structure of claim 1, wherein the drain via comprises a plurality of sub-holes distributed at intervals along a length direction, wherein a width direction of the drain via is a direction from the source region to the drain region, and the length direction is perpendicular to the width direction.

14. The transistor structure of claim 9, wherein a distance between the drain via and the gate conductor is greater than or equal to a minimum rule of a process node used to manufacture the transistor structure.

15. The transistor structure of claim 8, further comprising:
a) an interlayer dielectric layer covering the field isolation barrier layer and the semiconductor region; a source via penetrating through the interlayer dielectric layer and extending to the metal silicide layer; and
b) a first via penetrating through the interlayer dielectric layer and communicating with the drain via.

16. A method of making a transistor structure, the method comprising:
a) forming a source region and a drain region in a semiconductor region;
b) forming a gate dielectric layer on the upper surface of the semiconductor region;
c) forming a field isolation barrier layer on the semiconductor region, the field isolation barrier layer extending laterally from the gate dielectric layer at least above the drain region and covering the upper surface of the drain region;
d) forming a drain via penetrating through the field isolation barrier layer; and
e) filling the drain via to form a drain electrode, the drain electrode being in contact with the drain region.

17. The method of claim 16, wherein before the forming the drain via, the method further comprises forming a metal silicide layer on the surface of the source region, wherein the forming the metal silicide layer comprises:
a) forming a metal silicide blocking layer covering the surface of the semiconductor region and the field isolation barrier layer, the metal silicide blocking layer exposing the surface of the source region; and
b) forming a metal silicide layer on the exposed surface of the source region.

18. The method of claim 16, further comprising:
a) forming an interlayer dielectric layer covering above the semiconductor region;
b) forming a first via penetrating through the interlayer dielectric layer and a source via penetrating through the interlayer dielectric layer to extend to the metal silicide layer; and
c) wherein the drain via communicating with the first via is formed in the field isolation barrier layer by over-etching the field isolation barrier layer.
